(19) United States
(12) Patent Application Publication
(10) Pub. No.: US 2003/0089950 A1
(43) Pub. Date: May 15, 2003

(54) Bonding of silicon and silicon-germanium to insulating substrates

(76) Inventors: Thomas F. Kuech, Madison, WI (US); Peter D. Moran, Houghton, MI (US)

Correspondence Address: FOLEY & LARDNER, 150 EAST GILMAN STREET, P.O. BOX 1497, MADISON, WI, 53701-1497, US

(21) Appl. No.: 10/001,270

(22) Filed: Nov. 15, 2001

(51) Int. Cl. H01L 27/12

(52) U.S. Cl. 257/352

(57) ABSTRACT

Silicon and silicon-germanium semiconductor-on-insulator structures are formed with strong bonds between the silicon or silicon-germanium layer and the underlying insulating substrate with low defects in the semiconductor and minimal flaws in the bonding between the semiconductor layer and the substrate. An oxide layer is initially formed on the semiconductor wafer, and the wafer may then be annealed, if necessary, to drive off water from the oxide layer so that the oxide layer is well below the water saturation of the oxide. The surfaces of the oxide layer and the substrate are then cleaned and placed into contact at relatively low temperatures to effect a strong bond. The semiconductor layer may then be thinned by mechanical or chemical processes, or both, and the completed structure annealed to perfect the bond between the semiconductor layer and the substrate.

### REFERENCE TO GOVERNMENT RIGHTS

This invention was made with United States Government support awarded by the following agency: Navy N66001-00-M-1165. The United States Government has certain rights in this invention.

### FIELD OF THE INVENTION

This invention pertains generally to the field of semiconductor processing and particularly to the bonding of semiconductors to insulating substrates.

### BACKGROUND OF THE INVENTION

Silicon on insulator and silicon-germanium on insulator semiconductor structures are promising materials platforms for fabricating high-frequency digital, microwave, and radio frequency devices. The low dielectric loss, radiation hardness, and better thermal properties of silicon on sapphire (SOS) structures as compared to other silicon-on-insulator (SOI) structures points to SOS as an excellent candidate for use in forming devices for high-reliability microwave circuits. The use of SiGe/Si heterostructures has been shown to be useful for extending the high frequency performance of silicon-based electronics utilizing the exceedingly well developed silicon processing infrastructure. Thus, there is a significant demand for the development of effective techniques for incorporating Si and SiGe based electronics on sapphire and other insulating substrates to meet the increasing demand for cost-effective combined microwave/digital applications.

SOS structures are currently fabricated primarily by the heteroepitaxial growth of Si on sapphire (Al₂O₃). There is a large difference between silicon and sapphire in lattice constant and thermal expansion coefficients (TEC). The lattice mismatch and relatively high temperatures employed to grow and subsequently improve the structural quality of the SOS layers leads to the presence of a high density of extended defects in the silicon that propagates into subsequently grown SiGe layers.

SOS structures could alternatively be fabricated through the direct bonding of a silicon wafer to a sapphire substrate and the subsequent removal of the bulk silicon of the wafer to leave a thin layer of silicon on the sapphire substrate. A final silicon layer thickness on the order of 100 nm is suitable for many applications. The TEC mismatch between silicon and sapphire is a significant issue in this approach. Structural degradation of the silicon layer due to TEC mismatch must be mitigated by employing low temperature bonding and thinning processes so that the silicon layer is thin enough to elastically accommodate the TEC strain before the structure is exposed to any significant temperature cycles. The low temperature bonding process must therefore result in a bond strong enough to withstand the low temperature thinning process.

Another issue encountered in the fabrication of silicon on sapphire or other insulating substrates is the development of thinning processes which are capable of defining the final thickness of the SOS layer with the precision and accuracy needed for subsequent device fabrication processes. One present advantage of heteroepitaxial growth is the precision with which the layer thickness can be defined.

Another significant problem encountered in prior attempts to bond silicon wafers to insulating substrates is blistering and delamination of the silicon layer from the substrate during annealing. This effect is believed to be caused by hydroxyl groups and water trapped at the interface.

### SUMMARY OF THE INVENTION

In accordance with the present invention, silicon and silicon-germanium semiconductor-on-insulator structures are formed that have strong bonds between the silicon or silicon-germanium layer and the underlying insulating substrate, with low semiconductor defects and minimal flaws in the bonding between the semiconductor layer and the substrate.

In the present invention, a low defect bonding of the semiconductor layer to the insulating substrate is carried out by initially forming an oxide on the semiconductor wafer. If the oxide layer is formed by a process that leaves significant levels of hydroxyl groups in the oxide, the semiconductor wafer with the oxide layer thereon is then annealed to drive off water from the oxide layer so that the oxide layer is well below the water saturation of the oxide, thereby allowing the oxide to absorb water and hydroxyl groups during the bonding process which would otherwise interfere with the bonding or which would create bubbles or voids in the interface between the oxide layer and the substrate surface. The thickness of the oxide layer is selected to be thick enough to fully accommodate the water and hydroxyl groups (and incidental organic compounds) at the interface during the bonding process, effectively acting as a sponge to draw these species away from the interface. The oxide layer on a silicon wafer is preferably formed to a thickness of at least 70 nm.

After the semiconductor wafer (e.g., a silicon wafer or a silicon-germanium wafer) is annealed, if necessary, to drive water from the oxide layer on the wafer, the oxide layer and a surface of an insulating substrate layer (e.g., sapphire) are preferably cleaned (and polished if necessary), and the oxide layer surface on the semiconductor wafer and the substrate surface are contacted under pressure and annealed at a temperature at about 250° C. (or less) to bond the semiconductor wafer to the substrate wafer. Cleaning of the wafers preferably includes a plasma surface treatment followed by a megasonically excited deionized water rinse. The bonded wafers may then be annealed at higher temperatures if desired, e.g., above 400° C. and typically above 500° C. Preferably, before annealing the bonded wafers at higher temperatures, the semiconductor wafer is thinned so that the semiconductor layer is at a thickness of 2 μm or less, preferably 200 nm or less and most preferably in the range of 100 nm or less. For silicon and silicon-germanium semiconductors, appropriate insulating substrate wafers include sapphire, aluminum nitride, silicon carbide, and planarized glass. Thinning of the semiconductor may be carried out by various processes including mechanical grinding and chemical etching of the semiconductor and, in a preferred process, the semiconductor is initially mechanically ground and then subsequently etched by chemical etching to the final desired thickness. An etch stop layer may be formed in the semiconductor wafer which naturally terminates the etch at a selected thickness, followed by removal of the etch stop layer to leave the desired thinned semiconductor layer.

Preferably, the bonding of the semiconductor wafer to the substrate wafer is carried out by contacting a central portion of the oxide layer on the semiconductor wafer to the substrate surface while spacing the edges of the semiconductor wafer from the substrate wafer with spacers, thereby to bond the wafers together first at the central portion of the wafers, followed by removing the spacers and pressing the wafers together to bond the wafers together outwardly from the central portion of the wafers.

The oxide layer may be formed by growing the oxide from the semiconductor in a dry oxygen atmosphere, by carrying out plasma depositing of an oxide on the semiconductor wafer, such as depositing silicon dioxide on a silicon wafer, and by chemical vapor deposition.

The bonded wafers in accordance with the invention have a smaller number of structural defects in the silicon or silicon-germanium layer as compared to the structures produced in accordance with prior processes, especially after exposing the bonded structure to elevated temperatures. A relatively small breadth of a high resolution x-ray diffraction rocking curve for the bonded wafers of the invention is indicative of a relatively small number of structural defects in products produced in accordance with the present invention.

Further objects, features and advantages of the invention will be apparent from the following detailed description when taken in conjunction with the accompanying drawings.

### BRIEF DESCRIPTION OF THE DRAWINGS

In the drawings:

FIG. 1 is a simplified side view of a semiconductor wafer and an insulating substrate wafer to be bonded.

FIG. 2 is a simplified view of the semiconductor wafer being brought into initial central contact with the substrate during the bonding process.

FIG. 3 is a simplified view of the wafers of FIG. 1 after bonding.

FIG. 4 is a simplified view of the bonded wafers of FIG. 3 after thinning of the semiconductor wafer.

FIG. 5 is a simplified view of a semiconductor wafer structure and a substrate that may be bonded together in accordance with the invention.

FIG. 6 is a simplified view of the wafer and substrate of FIG. 5 after bonding.

FIG. 7 is a simplified view of the bonded wafers of FIG. 6 after removal of a top oxide layer.

FIG. 8 is a simplified view of another semiconductor wafer structure and insulating substrate to be bonded.

FIG. 9 is a simplified view of the semiconductor wafer and substrate of FIG. 8 after bonding.

FIG. 10 is a simplified view of the bonded wafers of FIG. 9 after removal of a top semiconductor layer.

FIG. 11 is a simplified view of the bonded wafers of FIG. 10 after the further removal of an oxide layer.

FIG. 12 is a diagram illustrating the hydroxyl groups at the interface between the semiconductor wafer and the substrate wafer.

FIG. 13 is a diagram of the interface of FIG. 12 illustrating the formation of water molecules from the hydroxyl groups and absorption of the water.

FIG. 14 is a diagram of the interface after absorption of the water molecules.

### DETAILED DESCRIPTION OF THE INVENTION

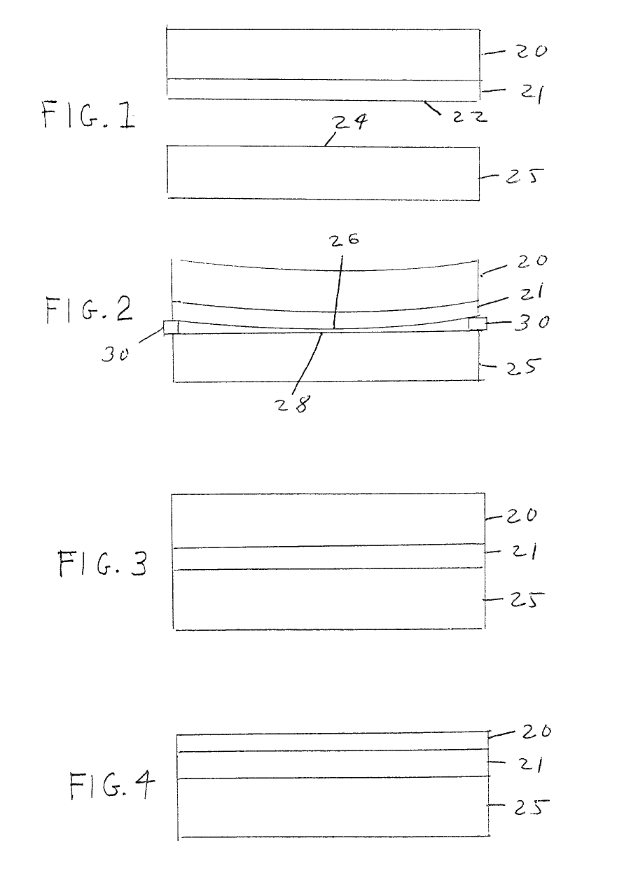

The process for carrying out the invention is discussed below with respect to the illustrative views of FIGS. 1-11. For purposes of illustrating the invention with respect to these figures, the semiconductor wafer is a silicon wafer and the substrate is sapphire (Al₂O₃), although it is understood that silicon-germanium (and other appropriate semiconductors) may be utilized as the semiconductor wafer and other insulating substrates such as silicon nitride, silicon carbide, and (preferably planarized) glass (e.g., glasses such as Corning 7059 glass which have a thermal coefficient similar to those of most semiconductors), may be utilized. The substrate may comprise any desired insulating material that has been planarized. For example, a layer of silicon dioxide may be formed on most substrates to planarize the substrate and provide a surface to which the semiconductor wafer can be bonded.

A basic process in accordance with the invention is illustrated with respect to FIGS. 1-4. As shown in FIG. 1, an initial (crystalline) silicon wafer 20 has a layer of oxide (SiO₂) 21 formed thereon. The oxide 21 may be formed in various ways, e.g., by growth on the silicon wafer in an oxygen atmosphere, by low pressure chemical vapor deposition, and by plasma deposition of the oxide. Where the oxide layer is formed with excess —OH groups and/or water, after formation of the oxide layer 21, the wafer 20 with the layer 21 thereon is annealed at an elevated temperature to drive out water from the oxide layer 21 so that the oxide will be in a condition capable of absorbing water that would otherwise interfere with the bonding process. It is generally not necessary to anneal an oxide formed by dry oxygen growth since the water content of the as-formed layer is typically sufficiently low. The annealing may be carried out at various temperatures, including relatively high temperatures (e.g., at 900° C. or more for, e.g., 10 minutes or more) in vacuum or in an atmosphere of gas that does not substantially react with the material of the silicon wafer and oxide layer, e.g., N₂ for a silicon wafer. The surface 22 of the layer 21 and the surface 24 of an insulating layer 25, e.g., Al₂O₃ as shown, may then be polished or otherwise planarized, if necessary, and are cleaned before contact. The substrate and oxide surfaces generally should have an RMS roughness of less than about 0.5 nm. This surface finish is typical of commercially available substrates that have been polished by the vendor. If the surfaces are rougher than this, then polishing may be necessary. The central portion of 26 of the surface 22 of the oxide layer 21 is preferably brought into contact initially with the central portion 28 of the substrate 25, with the edges of the semiconductor wafer spaced from the substrate 25 by spacers 30 as shown in FIG. 2. After initial bonding of the central portions 26 and 28, the spacers 30 are removed and pressure is then applied to the wafer 20 to provide contact outwardly from the central portions 26 and 28 to fully bond the wafer 20 to the substrate 25 in a uniform manner. The resulting multi-layer bonded structure is formed as illustrated in FIG. 3 in which the silicon layer 20 is relatively thick. A low temperature anneal (e.g., at 250° C.) may then be carried out to enhance bonding. After bonding, the silicon layer 20 is then reduced in thickness by, e.g., mechanical grinding or chemical etching, or mechanical grinding followed by chemical etching, to leave a semiconductor layer 20 which has a desired thickness generally less than 2 μm, preferably 200 μm or less and most preferably on the order of 100 nm or less. The oxide layer 21 is generally preferably at least 70 nm thick for a dry oxide, to provide capacity in the oxide layer 21 to absorb water or any incidental organic byproducts from the interface 32 between the oxide layer 21 and the substrate 25. The bonded structure of FIG. 4 may then be subjected to higher temperature annealing to perfect the bond at the interface 32 between the oxide layer 21 and the substrate 25. Annealing temperatures above 500° C. are typical, but lower temperature anneals may be used where subsequent applications do not require higher temperatures. If desired, an oxide layer (not shown) may be formed on the substrate 25 to planarize the substrate and facilitate the bond.

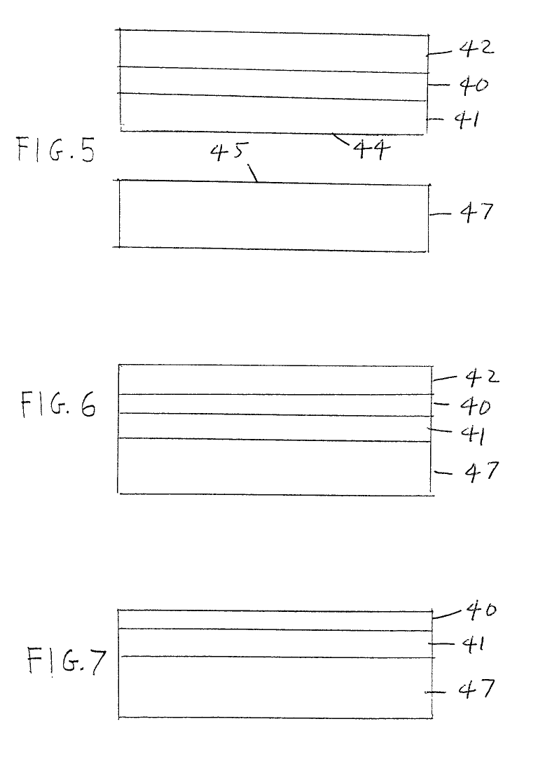

A variation on the foregoing process is illustrated with respect to FIGS. 5-7. The initial semiconductor wafer includes a layer of silicon 40 and layers of oxide 41 and 42 on each side of the silicon layer 40. The surface 44 of the oxide layer 41 is polished and cleaned, as is a surface 45 of the substrate wafer 47, and the substrate and semiconductor wafers are contacted together and bonded in the manner discussed above, to form the bonded structure of FIG. 6. The top silicon dioxide layer 42 may then be removed by etching using an etchant that removes the oxide but not silicon, to leave the bonded structure of FIG. 7 in which the silicon layer 40 is exposed for device formation or further processing. The layer of crystalline silicon 40 may initially be formed sufficiently thin to be at the desired thickness after bonding, or it may be mechanically or chemically thinned, as discussed above, to reach the desired thickness.

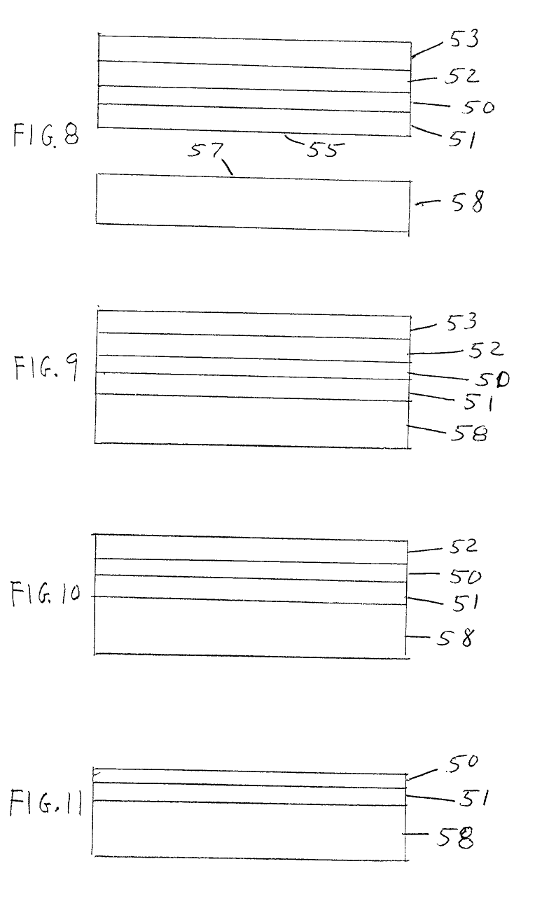

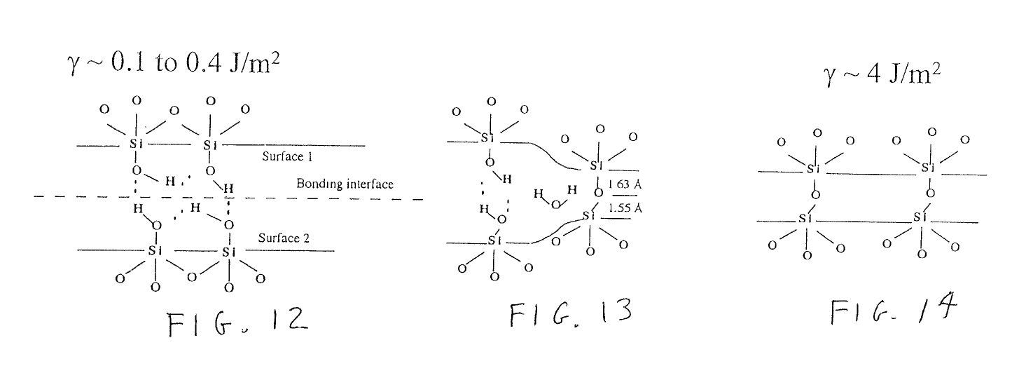

A further variation of the process is illustrated in FIGS. 8-11. As shown in FIG. 8, the semiconductor wafer includes a layer 50 of silicon, with a lower layer of oxide 51, an upper layer 52 of oxide, and a top layer 53 of silicon. The surface 55 of the oxide layer 51 and the surface 57 of the substrate 58 are prepared for contact and bonding as discussed above, resulting in the multi-layered bonded structure illustrated in FIG. 9. In the next step, the top layer 53 of silicon may be etched utilizing an etchant that etches silicon but stops at silicon dioxide, leaving the multi-layer structure of FIG. 10, followed by etching in an etchant which etches the oxide layer 52 but stops at silicon, leaving the multi-layer structure of FIG. 11 in which the silicon layer 50 is exposed and available for device formation. The multi-layer wafer structure of FIG. 8 may be appropriately used to produce an appropriately thin layer of silicon 50 which does not require further thinning. For example, the silicon layer 50 may be deposited or otherwise grown on the oxide layer 52 to a desired thickness, followed by deposition or growth of the interface oxide layer 51.

It is preferred that the surfaces of the oxide on the semiconductor wafer and the surface of the substrate be well cleaned before bonding occurs. A suitable cleaning process for the surfaces includes exposure of the surfaces to an O₂ plasma in a reactive ion etching arrangement for a suitable period of time, e.g., five minutes or more, followed by a megasonic de-ionized (Di) water rinse.

The effect of annealing the semiconductor wafer with the oxide thereon is illustrated with respect to the examples of a silicon dioxide layer grown on a silicon wafer shown in FIGS. 12-14. At initial bonding, as illustrated in FIG. 12, —OH groups dominate at the interface.

These -OH groups combine as shown in FIG. 13 to form H₂O which is absorbed into the silicon dioxide layer, leaving strong silicon-oxide bonds as illustrated in FIG. 14. The SiO₂ acts as a sponge for bond reaction products (H₂O, OH, H₂) to avoid bubble formation during annealing. The treatment of the silicon dioxide layer to remove water is important to allow the oxide layer to be unsaturated so that it can effectively absorb the reaction products. For example, an as-grown low pressure chemical vapor deposition (LPCVD) SiO₂ layer was, found to be saturated with at least 2.2×10²⁰ OH groups per cm³ (about 1/1,000 molecules). A 950° C. fifteen minute anneal in 50-sccm N₂ at 1 Torr was found to drive off at least 2.8×10²⁰ OH groups per cm³. Published data indicates that water is relatively soluble in SiO₂, i.e., 1.3-2.0×10²⁰ OH groups/cm³ at 700° C., and 0.5-1×10²⁰ OH group/cm³ at 1,000° C. SiO₂ can hold at least 1×10²⁰/cm³ at 550° C. The number of hydroxyl groups at the interface of two fully hydroxylated SiO₂ surfaces is about 9.2×10¹⁴/cm².

The required thickness of the oxide layer will generally depend on the subsequent processing temperatures that will be encountered and the amount of interfacial water at the bonded interface. For example, the thickness of the oxide layer may be significantly reduced if the bonded wafers will not be exposed to temperatures above 400° C.

The thickness of completely dry SiO₂ glass needed to act as a sponge for the OH species that initially coat the surface of the wafers prior to bonding, and subsequently form interfacial voids during exposure of the bonded structure to higher temperatures, can be estimated by assuming that the two wafer surfaces are completely coated with hydroxyl groups at room temperature, considering the solubility of OH groups in SiO₂, and requiring that the glass be sufficiently thick to absorb all of the OH groups that initially coat the surfaces of the wafers. The number of hydroxyl groups on a fully hydroxylated SiO₂ surface has been reported to be 4.6×10¹⁴/cm² (C. G. Armistead, A. J. Tyler, F. H. Hambleton, S. A. Mitchell, and J. A. Hockey, J. Phys. Chem. 73 3947 (1969)). The number of hydroxyl groups on a fully hydroxylated single-crystal sapphire wafer has been reported to be 1×10¹⁵/cm². (J. B. Peri, Journal of Physical Chemistry 69(1) 220 (1965)). The number of hydroxyl groups at the interface of a sapphire wafer bonded to an SiO₂-coated Si wafer will therefore be at most 1.5×10¹⁵ OH molecules/cm². We have measured the ability of SiO₂ to hold 2.9±0.7×10²⁰ OH molecules/cm³ at 675°. The thickness of the dry SiO₂ intermediary layer needed to absorb all of the OH groups generated at a SiO₂/sapphire bonded interface can therefore be estimated as 1.5×10¹⁵/2.2×10²⁰cm =70 nm. Depending on the dryness of the oxide layer, a thicker layer (e.g., 100 nm) may be desirable. Note that it is possible with the process described herein to decrease the thickness of the intermediary SiO₂ glass layer needed by limiting the number of hydroxyl groups on the surface of the wafers prior to bonding. This can be accomplished by thermal desorption of the OH molecules from the wafers at moderate temperatures in a vacuum environment. This typically comes at the expense of decreasing the low temperature bond strength. The low temperature bond strength must be maintained at a sufficient level to be able to withstand the mechanical thinning of the silicon wafer prior to exposure of the bonded structure to temperatures higher than 250° C. Otherwise, as was seen in prior processes, the thermal expansion coefficient mismatch between the silicon and sapphire leads to catastrophic failure of the bonded interface or structural degradation of the silicon layer.

The following is an example of the process of the present invention for bonding silicon-on-insulator (SOI) to sapphire. This example is for illustrative purposes only and the invention is not limited to the process as exemplified.

1. Start with a commercially available SOI wafer (total thickness on the order of 0.5 mm with top silicon layer thickness ˜300 nm and a buried oxide layer thickness ˜400 nm) and a commercially available sapphire substrate. The prime-grade surface finish on these wafers is generally sufficiently smooth to enable wafer bonding so that no subsequent polishing is usually necessary.

2. Form a top oxide layer on the SOI by exposing the SOI wafer to a dry oxygen ambient at 1050° C. in a standard oxidation furnace. The time in the oxidation furnace determines the thickness of the oxide formed and the reduction in the Si layer thickness that will be ultimately transferred to the sapphire wafer (˜200 nm of top oxide formed in ˜200 minutes of oxidation results in a reduction of ˜80 nm in the thickness of the top Si layer that will eventually be transferred to the sapphire wafer).

3. Expose the oxidized SOI wafer and the sapphire wafer to an oxygen plasma to chemically clean the surfaces. Typical process parameters are: exposure of the wafers for 5 minutes to a plasma created by flowing 10 sccm of oxygen in a parallel plate plasma tool (wafers resting on the ungrounded plate) with a base pressure of ˜10 mtorr operated at 200W of forward RF power at a frequency of 13.6 MHz.

4. Remove particulates from the surface of the wafers by mounting the wafers on a chuck spinning at 2000 rpm, subsequently applying megasonically excited deonized (DI) water at a rate of 1.5 liters/minute through a nozzle that sweeps over the wafer from center to edge for ˜1 minute, and then spinning the wafers dry at 2000 rpm for approximately 1 minute.

5. Load the sapphire and SOI wafers face-to-face in a vacuum chamber on a heating element. The wafers should be separated by three 50 micron thick spacer flags equidistantly spaced at the wafers' periphery.

6. Define a vacuum in the chamber of 10⁻⁴mbar and heat the bottom chuck to 105° C. Hold the separated wafers at this temperature for 10 minutes.

7. Bring the wafers into contact at their center using a pin with a cross-sectional diameter of approximately 5 mm applying a force of approximately 75 N.

8. Remove the flags separating the wafers at their periphery.

9. Remove the bonded wafers from the vacuum chamber.

10. Anneal the bonded structure at 250° C. for approximately 24 hours.

11. Remove the bulk of the Si in the SOI wafer by mechanically grinding the bonded wafer pair to within approximately 60 microns of the bonded interface.

12. Remove the remaining Si (to the buried oxide interface) by immersing the bonded wafer in TMAH (25% by weight in water) heated to 90° C. for approximately 3 hours. This etch will stop on what was originally the buried oxide in the SOI wafer. This buried oxide is now a capping oxide on the SOS wafer. This protective oxide cap can be removed without impacting the underlying thin Si layer by immersion in dilute HF.

For reasons discussed above, preferred processing conditions in accordance with the invention include cleaning of the substrates utilizing plasma surface treatment and subsequent megasonically excited DI water rinsing. This is followed by a prebond, in-vacuum, low temperature thermal desorption of a portion of the OH groups and use of an intermediary dry oxide layer. The bonded structures are subsequently annealed at relatively low temperatures, e.g., 250° C., followed by precision thinning of the semiconductor (silicon) wafer. The bonded wafer pair has a sufficiently strong bond strength to withstand the mechanical thinning of the silicon wafer prior to exposures to temperatures greater than 250° C.,and the large number of interfacial voids that would otherwise form due to the desorption of OH groups from the bonded interface at higher temperatures are avoided because of absorption of such groups by the intermediary oxide. The product formed by this process is distinguished by the absence of a large number of extended structural defects in the silicon layer of, e.g., silicon-on-sapphire structures in contrast to the prior art bonded structures. The improved bonding in accordance with the present invention can be measured through inspection of the breadth of a diffraction peak in a high resolution x-ray diffraction rocking curve measurement of the silicon-on-sapphire structure. Whereas the breadth of the peak corresponding to the silicon layer of a silicon-on-sapphire structure formed by the prior art has a full-width-at-half maximum (FWHM) on the order of 1,000 arcseconds due to the peak broadening induced by the large number of extended structural defects in the silicon layer, the peak of the diffraction rocking curve of the silicon layer in the structure formed by the present invention has a small FWHM on the order of 100 arcseconds, due to the absence of the broadening effects of the extended defects that are present in the prior art structures.

It is understood that the invention is not confined to the embodiments set forth herein as illustrative, but embraces all such forms thereof as come within the scope of the following claims.

What is claimed is:

1. A method of bonding semiconductor to an insulating substrate comprising:
(a) forming a dry oxide layer to a layer thickness of at least 70 nm on a semiconductor wafer comprising at least a layer of silicon or silicon-germanium;
(b) cleaning the oxide layer on the semiconductor wafer and cleaning a surface of an insulating substrate wafer;
(c) contacting the cleaned surface of the oxide layer on the semiconductor wafer and the cleaned substrate surface under pressure to bond the semiconductor wafer to the substrate wafer;
(d) annealing the bonded semiconductor wafer and substrate wafer to improve the bond; and
(e) thinning the silicon or silicon-germanium layer of the semiconductor wafer to a thickness of 2 μm or less.

2. The method of claim 1 wherein the step of annealing the bonded semiconductor wafer and substrate wafer is carried out at a temperature of about 250° C. or less.

3. The method of claim 1 wherein in the step of thinning the silicon or silicon-germanium layer of the semiconductor wafer, the silicon or silicon-germanium layer is thinned to a thickness of 100 nm or less.

4. The method of claim 1 wherein the step of thinning the silicon or silicon-germanium layer is carried out by mechanically grinding followed by chemical etching of the silicon or silicon-germanium.

5. The method of claim 1 wherein the substrate wafer is selected from the group consisting of sapphire, aluminum nitride, silicon carbide, and planarized glass.

6. The method of claim 1 wherein the step of contacting the oxide layer on the semiconductor wafer to the substrate wafer is carried out by contacting a central portion of the surface of the oxide layer to the substrate surface while spacing the edges of the semiconductor wafer from the substrate wafer with spacers to bond the wafers together first in the central portion of the wafers, and then removing the spacers and applying pressure to the wafers to provide contact outwardly from the central portion of the wafers to fully bond the wafers together.

7. The method of claim 1 wherein the step of contacting the oxide layer to the substrate is carried out in an atmosphere of an inert gas or in a vacuum.

8. The method of claim 1 wherein the step of forming the oxide layer is carried out by growing the oxide on the semiconductor wafer in an oxygen atmosphere.

9. The method of claim 1 wherein the step of forming the oxide layer is carried out by chemical vapor deposition followed by annealing to drive water from the oxide layer.

10. The method of claim 9 wherein the step of annealing to drive water from the oxide layer is carried out at a temperature of at least 900° C. for at least 10 minutes in a vacuum or an atmosphere of gas that does not substantially react with the material of the silicon wafer and oxide layer.

11. The method of claim 1 wherein the step of forming the oxide layer is carried out by plasma depositing silicon dioxide on the semiconductor wafer followed by annealing to drive water from the oxide layer.

12. The method of claim 1 further including forming a layer of oxide on both sides of the semiconductor wafer.

13. The method of claim 12 further including, after the step of contacting the oxide layer to the substrate wafer to bond the semiconductor wafer to the substrate wafer, thinning the semiconductor wafer by chemically etching the oxide layer from the semiconductor wafer on the side of the silicon wafer opposite that which is bonded to the substrate.

14. The method of claim 1 includes the further step of annealing the bonded semiconductor wafer and the substrate wafer at temperatures above 4000° C.

15. The method of claim 1 wherein the step of cleaning the oxide layer and a surface of the substrate are carried out by exposing the semiconductor wafer and substrate wafer to an oxygen plasma.

16. The method of claim 15 wherein, after exposing the semiconductor wafer and the substrate wafer to an oxygen plasma, the further step of applying deionized water to the wafers to remove particulates from the surface of the wafers, and then drying the wafers.

17. A method of bonding a semiconductor to an insulating substrate comprising:
(a) forming a dry silicon dioxide layer to a layer thickness of at least 70 nm on a semiconductor wafer comprising at least a layer of silicon;
(b) cleaning the silicon dioxide layer on the semiconductor wafer and cleaning a surface of an insulating substrate wafer;
(c) contacting the cleaned silicon dioxide layer on the semiconductor wafer and the cleaned substrate surface under pressure and annealing at a temperature at or less than about 250° C. to bond the semiconductor wafer to the substrate wafer; and
(d) thinning the silicon layer of the semiconductor wafer to a thickness of 2 μm or less.

18. The method of claim 17 wherein in the step of thinning the silicon layer of the semiconductor wafer, the silicon is thinned to a thickness of 100 nm or less.

19. The method of claim 17 wherein the step of thinning the silicon layer is carried out by mechanically grinding the silicon followed by chemical etching of the silicon.

20. The method of claim 17 wherein the substrate wafer is selected from the group consisting of sapphire, aluminum nitride, silicon carbide, and planarized glass.

21. The method of claim 17 wherein the step of contacting the silicon dioxide layer on the semiconductor wafer to the substrate wafer is carried out by contacting a central portion of the surface of the silicon dioxide layer on the semiconductor wafer to the substrate surface while spacing the edges of the semiconductor from the substrate wafer with spacers to bond the wafers together first in the central portion of the wafers, and then removing the spacers and applying pressure to the wafers to provide contact outwardly from the central portion of the wafers to fully bond the wafers together.

22. The method of claim 17 wherein the step of contacting the silicon dioxide layer to the substrate is carried out in an atmosphere of an inert gas or in a vacuum.

23. The method of claim 17 further including forming a layer of silicon dioxide on both sides of the semiconductor wafer.

24. The method of claim 23 further including, after the step of contacting the silicon dioxide layer to the substrate wafer to bond the semiconductor wafer to the substrate wafer, thinning the semiconductor wafer by chemically etching the silicon dioxide layer from the semiconductor wafer on the side of the semiconductor wafer opposite that which is bonded to the substrate.

25. The method of claim 17 including the further step of annealing the bonded semiconductor wafer and the substrate wafer at temperatures above 400° C.

26. The method of claim 17 wherein the step of cleaning the silicon dioxide layer and a surface of the substrate are carried out by exposing the semiconductor wafer and the substrate wafer to an oxygen plasma.

27. The method of claim 26 wherein, after exposing the semiconductor wafer and the substrate wafer to an oxygen plasma, the further step of applying deionized water to the wafers to remove particulates from the surface of the wafers, and then drying the wafers.

28. The method of claim 17 wherein the step of forming the silicon dioxide layer is carried out by growing the silicon dioxide on the silicon layer of the semiconductor wafer in an oxygen atmosphere.

29. The method of claim 17 wherein the step of forming the silicon dioxide layer is carried out by chemical vapor deposition followed by annealing to drive water from the silicon dioxide layer.

30. The method of claim 30 wherein the step of annealing to drive water from the oxide layer is carried out at a temperature of at least 900° C. for at least 10 minutes in a vacuum or an atmosphere of gas that does not substantially react with the material of the silicon wafer and oxide layer.

31. The method of claim 17 wherein the step of forming the silicon dioxide layer is carried out by plasma depositing silicon dioxide on the semiconductor wafer followed by annealing to drive water from the silicon dioxide layer.

32. A bonded silicon-on-sapphire structure comprising:
(a) a sapphire substrate;
(b) a semiconductor wafer bonded to the sapphire substrate, the semiconductor wafer having at least a layer of silicon with a thickness of 100 nm or less and a layer of silicon dioxide of a thickness of at least 70 nm in contact with the sapphire substrate, the x-ray diffraction rocking curve of the silicon layer having a full-width-at-half maximum on the order of 100 arcseconds or less.
